(19) United States
(12) Patent Application Publication
(10) Pub. No.: US 2006/0216929 A1
(43) Pub. Date: Sep. 28, 2006

(54) Etch stopless dual damascene structure and method of fabrication

(76) Inventors: Hyun-Mog Park, Portland, OR (US); Chin-Chang Cheng, Portland, OR (US)

Correspondence Address: INTEL/BLAKELY, 12400 WILSHIRE BOULEVARD, SEVENTH FLOOR, LOS ANGELES, CA, 90025-1030, US

(21) Appl. No.: 11/092,298

(22) Filed: Mar. 28, 2005

(51) Int. Cl. H01L 21/4763

(52) U.S. Cl. 438/637

(57) ABSTRACT

An etch stopless interconnect structure. According to embodiments of the present invention, a via opening is formed in an interlayer dielectric over a metal layer to expose a portion of the metal layer. The opening is then partially filled with a gap fill material. The opening is then filled with a sacrificial material wherein the sacrificial material is formed on the gap fill material. A trench is then formed in the interlayer dielectric including a portion of the opening filled with the sacrificial material. The sacrificial material is then removed from the opening. The trench and opening are then filled with a conductive film.

### BACKGROUND OF THE INVENTION

1. Field of the Invention

The present invention relates to the field of integrated circuit manufacture and more specifically to a method of forming an etch stopless dual damascene structure.

2. Discussion of Realated Art

Modern integrated circuit, such as microprocessors, are made up of literally millions of transistors formed in a silicon substrate. The transistors are coupled together into functional circuits through the use of multiple levels of “backend” metallization. The backend metallization typically includes multiple levels of metal interconnects separated by interlevel dielectrics and connected together by conductive vias.

An example of a conventional method of forming interconnect structure utilizing a “dual damascene” process is illustrated in Figures 1A-1F. In a dual damascene process, a substrate having a first level of metallization 102 formed in an interlayer dielectric 101 is provided. The first level of metallization typically includes a bulk copper layer 104 surrounded by an adhesion/barrier layer 106, such as a tantalum/tantalum nitride film. An etch stop layer 108, such as silicon nitride, is formed over the interconnect 102 and the interlayer dielectric 101. A second interlayer dielectric 110 is then formed over the etch stop layer 108 as shown in FIG. 1A. The etch stop layer helps prevent out diffusion of copper atoms out of interconnect 102 and into the overlying interlayer dielectric 110.

Next, via opening 112 is formed in the interlayer dielectric 110 as shown in FIG. 1A The etchant used to form the via opening 112 stops on the “etch stop” layer 108.

Next, a sacrificial light absorbing material (SLAM) 114 is formed in via opening 112 and onto etch stop layer 108 and over ILD 110 as shown in FIG. 1B. A trench 116 is then etched into the upper portion of the interlayer dielectric 110 and over the filled via opening 112 as shown in FIG. 1C. After forming trench 116, the SLAM material 114 is removed from the top of ILD 110 and via 112 to expose the underlying etch stop layer 108 as illustrated in FIG. 1D. The etch stop layer in the via opening 112 is then removed as illustrated in FIG. 1E. After removal of the etch stop layer 108 a diffusion/barrier layer 118 and bulk metal fill material 120 can be formed in the via opening and trench to form an interconnect and via in contact with underlying interconnection 102 as illustrated in FIG. 1F.

As device dimensions are continually decreased in order to further increase the packing density of transistors into an integrated circuit, interconnects are also packed closer together resulting in capacitive coupling between adjacent interconnects 120 and between interconnects formed above and below one another. In order to reduce the capacitive coupling between adjacent and sub-adjacent interconnects, low dielectric constant (dielectric constant k<4.0) in interlayer dielectrics can be utilized. Unfortunately, etch stop layers 108, such as silicon nitride, have high dielectric constants which increase the effective dielectric constant of the interlayer dielectric. Simply removing the etch stop layer 108, would enable the out-diffusion of copper atoms from the interconnect 102 and into the overlying interlayer dielectric 110. Such an out-diffusion of copper atoms can lead to electromigration failures. Additionally, removal of the etch stop layer 108 would expose the underlying interconnect 102 to attacked by the harsh chemicals and clean processes used to remove the SLAM material 114 (FIG. 1C). The strong wet chemistry used to remove the SLAM material and clean the via can etch into and undercut the interconnect 102. Etching into and undercutting interconnect 102 could make it difficult for the barrier layer deposition process to fully cover the undercut which could lead to device failure.

### BRIEF DESCRIPTION OF THE DRAWINGS

FIG. 1A-1F is an illustration of a cross-sectional view of a method of forming a conventional dual damascene structure

FIG. 2A-2I are cross-sectional illustrations of a method of forming an etch stopless dual damascene structure in accordance with an embodiment of the present invention.

FIG. 3 is an illustration of a system in accordance with an embodiment of the present invention.

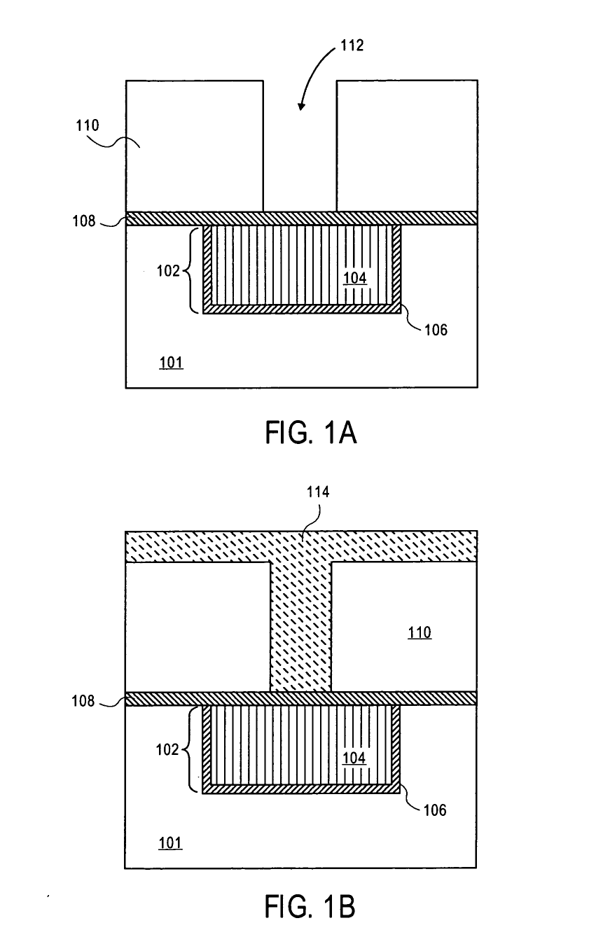

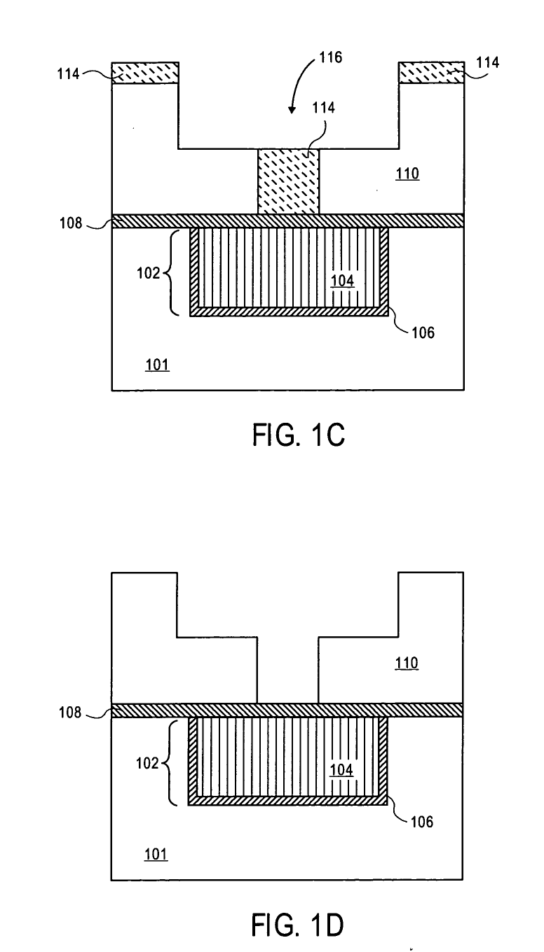

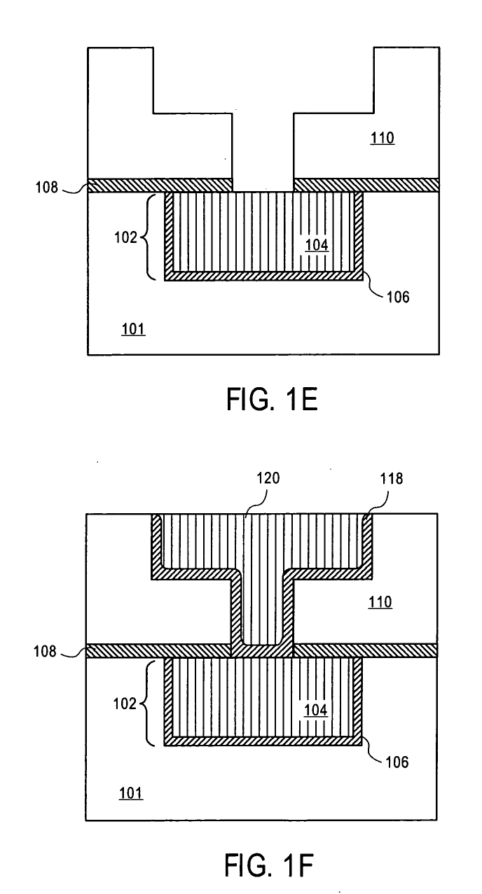

### DETAILED DESCRIPTION OF THE PRESENT INVENTION

Embodiments of the present invention are an etch stopless dual damascene structure and its method of fabrication. In the following description numerous specific details are set forth in order to provide a thorough understanding of the present invention. In other instances, however, well known semiconductor processing techniques and equipment have not been set forth in particular detail in order to not unnecessarily obscure the present invention.

An etch stopless dual damascene structure and its method of fabrication is described. Embodiments of the present invention describe a method of forming a dual damascene structure without the use of a etch stop layer. In an embodiment of the present invention, a via opening is formed through an interlayer dielectric to expose an underlying metal layer to which a contact is desired. The via opening is then partially filled with a partial gap fill material, such as a corrosion resistant metal layer or dielectric film. Next, the remainder of the via opening is filled with a sacrificial material, such as sacrificial light absorbing material (SLAM), and a trench etched into the upper inter portion of the interlayer dielectric including the portion of the SLAM filled via opening. The remaining portion of the SLAM material is then removed from the opening. The partial gap fill material protects the underlying metal layer from chemical attack by the chemicals used to remove the SLAM material and to clean the via opening. In this way, the chemicals cannot etch through the cap layer and into the underlying copper layer and cause reliability issues. If the partial gap fill material is a dielectric film, it can be removed after the SLAM removal and the trench/via clean. If the partial gap fill material is a conductive film, it can remain in the bottom portion of the via and the trench and via metallization can be formed directly onto the conductive partial gap fill material. The present invention provides a method of fabrication of a dual damascene structure without the need for an etch stop layer to protect the underlying conductive film. Elimination of the high dielectric constant etch stop layer reduces the effective dielectric constant of the interlayer dielectric which in turn improves the electrical performance of the interconnect structure.

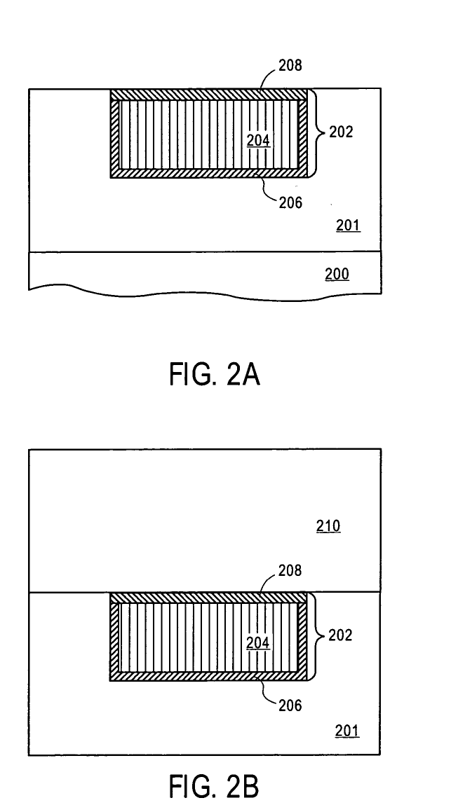

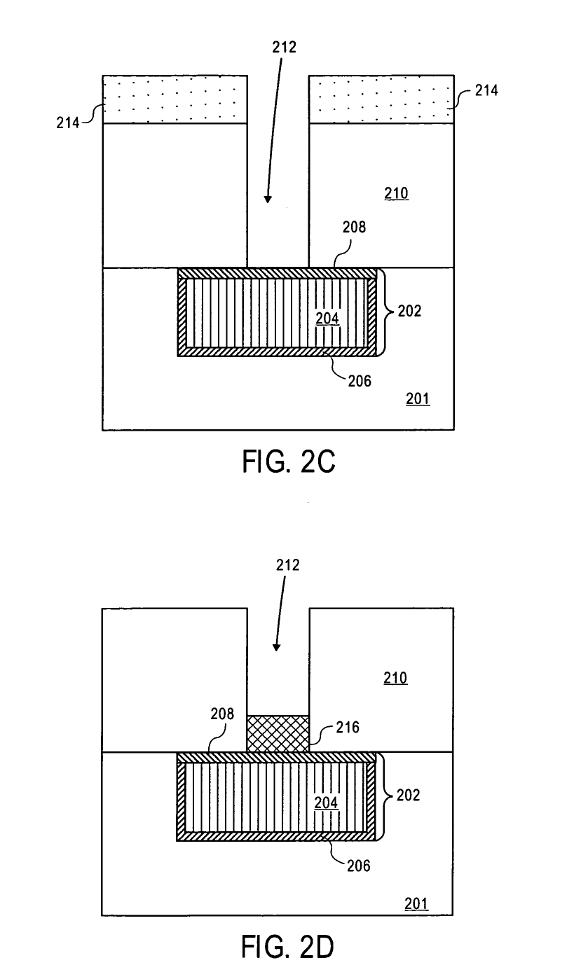

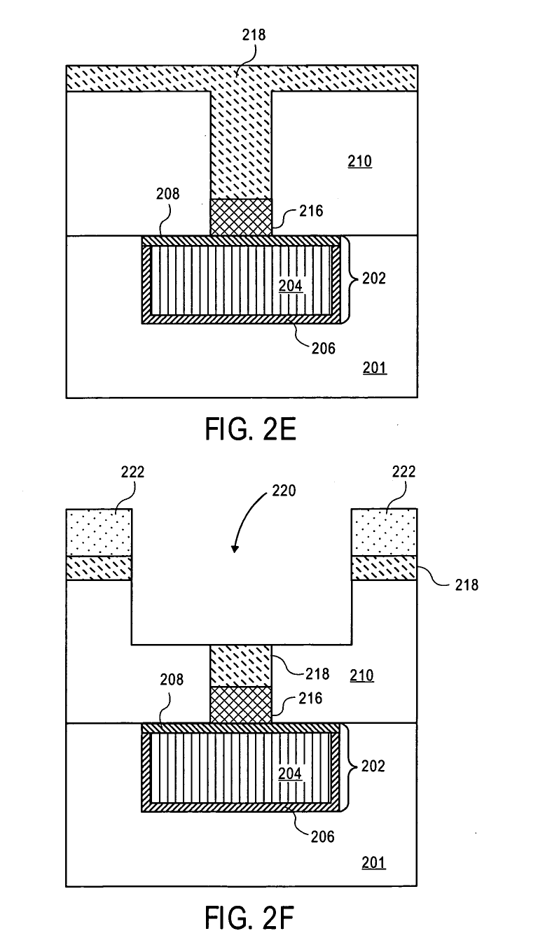

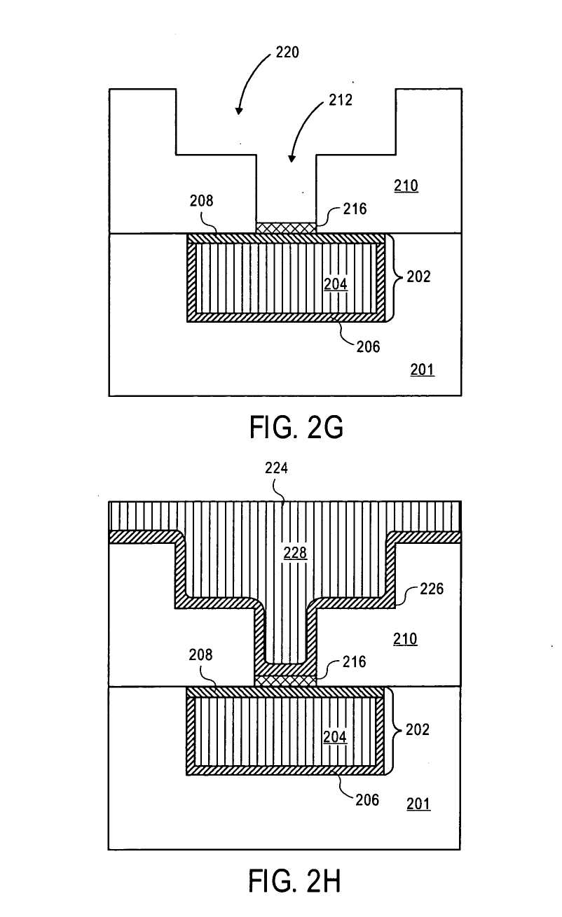

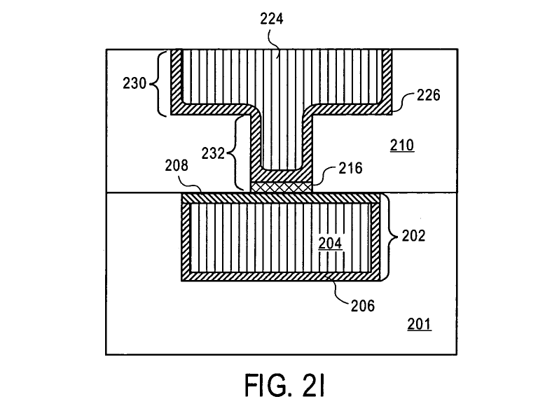

A method of forming a dual damascene structure without an etch stop layer in accordance with an embodiments of the present invention as illustrated in FIGS. 2A-2I. Embodiments of the present invention can be used to form metal interconnects and vias in dual damascene process. Metal interconnects and vias are typically part of a “backend” process used to electrically interconnect various electrical devices, such as capacitors and transistor formed in a semiconductor substrate, such as a monocrystalline silicon substrate or a silicon on insulator (SOI) substrate into functional circuits. Backend process can be utilized to interconnect transistors and capacitors into functional circuits, such as microprocessors, digital signal processors, embedded controllers and memory devices, such as flash memories or dynamic random access memories. Typically, the backend includes multiple levels of metal interconnects (e.g., nine), coupled together by conductive vias. In a dual damascene fabrication process, as well known in the art, the interconnects and vias of a level are formed in the same interlayer dielectric and are filled with the same deposition step.

Embodiment of the present invention begin with a semiconductor substrate, such as a silicon monocrystalline substrate or a silicon on insulator (SOI) substrate, in which is formed a plurality of active devices, such as capacitors and transistors. An interlayer dielectric 201 is then formed over the substrate as shown in FIG. 2A. A metal interconnect 202 is then formed in the top portion of the interlayer dielectric (ILD) 201 as shown in FIG. 2A. Although, the present invention will be described with respect to the formation of a second level interconnect and via which contacts a first level interconnect (interconnect 202), it is to be appreciated that the present invention can be used to form any level of metallization interconnects (metal 1, metal 2, metal 3) and vias which are to make contact with a previously formed metal or conductive film.

Interlayer dielectric (ILD) 201 can be formed from any suitable and well known interlayer dielectric material, such as but not limited to silicon dioxide (SiO₂). In an embodiment of the present invention, interlayer dielectric 201 is formed from a low dielectric constant (i.e., low k) material. A low dielectric constant material is a material having a dielectric constant (k) less than the dielectric constant of silicon dioxide (SiO₂) which has a dielectric constant (k) of approximately 4.0. In the embodiment of the present invention, interlayer dielectric comprises a low dielectric constant material, such as but not limited to fluorine doped SiO₂ (SiOF) film, carbon doped oxide (CDO) film, a porous silicon dioxide film, or a zeolite film.

In an embodiment of the present invention, the metal interconnect 202 includes a bulk copper or copper alloy film 204. The copper or copper alloy film 204 can be formed by any well know process, such as electrolytic deposition. In an embodiment of the invention, interconnect 202 includes an adhesion/barrier layer 206, such as tantalum or tantalum nitride or combinations thereof. Additionally, in an embodiment of the present invention, the interconnect 202 includes a cap layer 208. The cap layer is formed of a metal film and to a thickness sufficient to prevent the out diffusion of atoms from interconnect 202 into a subsequently formed ILD 210. In an embodiment of the present invention, the cap layer 208 material is a cobalt alloy, such as but not limited to an CoB, CoP, CoBP, CoW, CoWB, CoWP, CoMo, CoMoP, CoMoBP,CoRe, CoReB, CoReP, CoReBP. In an embodiment of the present invention, the cap layer 208 is a nickel alloy, such as but not limited to NiB, NiP, NiBP, NiW, NiWB, NiWP, NiMo, NiMoP, NiMoBP, NiRe, NiReB, NiReP, NiReBP. In an embodiment of the present invention, the cap layer 208is a nickel cobalt alloy, such as but not limited to NiCoB, NiCoP, NiCoBP, NiCoW, NiCoWB, NiCoWP, NiCoMo, NiCoMoP, NiCoMoBP, NiCoRe, NiCoReB, NiCoReP, NiCoReBP. In an embodiment of the present invention, the metal layer is selectively deposited onto the exposed metal interconnect 202. In a selective deposition process, the cap layer 208 forms only on exposed metal layers, such as exposed portion of interconnect 202 and not on exposed portions of interlayer dielectric 201. A cobalt, nickel, or cobalt-nickel alloy layer can be selectively electrolessly deposited by exposing the interconnect to an electroless deposition solution comprising a source of cobalt or nickel, such as but not limited to chloride or sulfate salts, a reducing agent, such as but not limited to formaldehyde, hypophosphite and dimethyl amine borane (DMAB) and sources of the other elements to be alloyed with the cobalt and/or nickel atoms, such as but not limited to sources of phosphorous (P), tungsten (W), boron (B) and molibium (Mo). In an embodiment of the present invention, the top surface of interconnect 202 is substantially planar with the top surface of interlayer dielectric 201 as shown in FIG. 2A.

Next, as shown in FIG. 2B, an interlayer dielectric 210 is formed over interconnect 202 and ILD 201 as shown in FIG. 2B. Interlayer dielectric 210 can be any well known and suitable interlayer dielectric material, such as silicon dioxide. In an embodiment of the present invention, interlayer dielectric layer 210 is a low k dielectric, such as but not limited to fluorine doped silicon dioxide, carbon doped oxide, porous dielectric, and a zeolite layer. Any well known and suitable technique, such as chemical vapor deposition (CVD), high density plasma (HDP) and plasma enhanced chemical vapor deposition (PECVD) can be used to deposit ILD 210. ILD 210 is formed to a thickness required for the next level of interconnects and vias. After deposition of interlayer dielectric 210, the top surface of interlayer dielectric 210 may be planarized by, for example, chemical mechanical polishing (CMP) to form a planar top surface. It is to be appreciated that in embodiments of the present invention, ILD 210 is formed directly onto interconnect 202 and ILD 201 without an intermediate etch stop layer. That is, in an embodiment of the present invention, there are no etch stop layers or other high dielectric constant films (k>4.0) formed on top of interlayer dielectric 201 and interconnect 202 prior to the formation of interlayer dielectric 210. In this way, the effective dielectric constant of interlayer dielectric 210 can remain low (e.g., <4.0) enabling the formation of a high performance interconnect structure.

Next, as shown in FIG. 2C, a via opening 212 is formed through ILD 210 to exposes a portion of interconnect 202. Via opening 212 can be formed by any well known technique, such as by forming a photoresist mask 214 utilizing well known photolithography techniques, such as masking, exposing and developing, to define a location on ILD 210 where via opening 212 is to be formed and then utilizing well known etching techniques to etch opening 212 in alignment with the photoresist mask 214. After etching opening 212, the photoresist mask 214 can be removed by well known techniques, such as by ashing. Next, if desired, the opening 212 can be cleaned with a cleaning solution, such as a fluorine-containing solvent based stripper.

Next, as shown in FIG. 2D, the via opening 212 is partially filled with a partial gap fill material 216. The partial gap fill material 216 is formed directly onto interconnect 202 and fills the bottom portion of opening 212. The partial gap fill material 216 is used to prevent the underlying metal interconnect 202 from being attacked by the chemical etchant used to remove a subsequently formed sacrificial material, such as SLAM, used in the subsequent formation of the trench portion (interconnect) of the dual damascene structure. Accordingly, in an embodiment of the present invention, the partial gap fill material 216 is formed of a material which can withstand the chemistry and etchant used to remove the subsequently formed sacrificial material. In an embodiment of the present invention, the partial gap fill material 216 is formed from a material which has an etch selectivity of approximately 10:1 and ideally at least 20:1 with the chemical etchant used to remove a sacrificial material formed in opening 212. Additionally, in an embodiment of the present invention, the partial gap fill material 216 is deposited to a thickness sufficient to protect the underlying metal layer 202 during the removal of the sacrificial material (e.g., SLAM). In an embodiment of the present invention, the partial gap fill material 216 is formed to a thickness of between 200-400 Å.

In an embodiment of the present invention, the partial gap fill material 216 is a conductive material. In an embodiment of the present invention, the partial gap fill material 216 is a corrosion resistant metal layer. In an embodiment of the present invention, the partial gap fill material 216 is a cobalt alloy, such as but not limited to an CoB, CoP, CoBP, CoW, CoWB, CoWP, CoMo, CoMoP, CoMoBP,CoRe, CoReB, CoReP, CoReBP. In an embodiment of the present invention, the gap fill material is a nickel alloy, such as but not limited to NiB, NiP, NiBP, NiW, NiWB, NiWP, NiMo, NiMoP, NiMoBP, NiRe, NiReB, NiReP, NiReBP. In an embodiment of the present invention, the partial gap fill material 216 is a nickel cobalt alloy, such as but not limited to NiCoB, NiCoP, NiCoBP, NiCoW, NiCoWB, NiCoWP, NiCoMo, NiCoMoP, NiCoMoBP, NiCoRe, NiCoReB, NiCoReP, NiCoReBP. In an embodiment of the present invention, the partial gap fill material 216 is a metal layer selectively deposited onto the exposed metal interconnect 202. In an embodiment of the present invention, the partial gap fill material 216 is selectively deposited onto the interconnect 202 utilizing an electroless deposition process so that it fills up from the bottom of the via opening. In a selective deposition process, the partial gap fill material 216 forms only on exposed metal layers, such as exposed portion of interconnect 202 and does not form on dielectric surfaces, such as the top of ILD 210 of the sidewalls of via opening 212. A cobalt, nickel, or cobalt-nickel alloy layer can be selectively deposited by exposing the interconnect to an electroless deposition solution comprising a source of cobalt or nickel, such as but not limited to chloride or sulfate salts, a reducing agent, such as but not limited to formaldehyde, hypophosphite and dimethyl amine borane (DMAB) and sources of the other elements to be alloyed with the cobalt and/or nickel atoms, such as but not limited to sources of phosphorous, tungsten, boron and molibium. Although A metal partial gap fill material 216 is ideally formed by a selective electrolytic deposition processes, other methods such as atomic layer deposition (ALD), chemical vapor deposition (CVD) may be used.

In an embodiment of the present invention, the partial gap fill material 216 is a dielectric film, such as but not limited to silicon nitride and silicon carbide. A dielectric partial gap fill material 216 can be form by, for example, chemical vapor deposition (CVD), atomic layer deposition (ALD) and sputtering. It is to be appreciated that such deposition processes blanket deposit films such that they not only form in the bottom of opening 212 but also onto the top surface of the interlayer dielectric 210 as well as onto the sidewalls of opening 212.

Next, a sacrificial material 218 is formed in opening 212 on the top of partial gap fill material 216 as shown in FIG. 2E. In an embodiment of the present invention, the sacrificial material 218 is a sacrificial light absorbing material (SLAM) to enable the formation of a trench in the top portion of ILD 210 for the fabrication of a metal interconnect. The sacrificial material 218 ideally has 1:1 etch selectivity with respect to the interlayer dielectric 210. Additionally, in an embodiment of the present invention, the sacrificial material 218 provides an anti-reflective coating for the lithographic processing of a photoresist mask used to define the trench location. As such, in an embodiment of the present invention, the sacrificial material 218 is formed on the top surface of ILD 210 and has a composition enabling the sacrificial material 218 to act as an anti-reflective coating (ARC) for exposure light at a wavelength of 248 nanometers and in another embodiment at a wavelength of 193 nanometers. In an embodiment of the present invention, the sacrificial material is a silicon oxygen carbon and hydrogen (SiOCH) containing material. Examples of suitable SLAM materials include, but are not limited to DUO193 and DUO248 anti-reflective coating manufactured by Honeywell Corporation. The sacrificial material 218 can be deposited by any well known technique, such as but not limited to spin coating and chemical vapor deposition (CVD).

Next, a trench 220 is etched into the top portion of ILD 210 as illustrated in FIG. 2F. Trench 220 is formed over a portion of opening 212 filled with sacrificial material 218 as illustrated in FIG. 2F. Trench 220 can be etched by forming a photoresist mask 222 on sacrificial films 218/ILD210 which defines the location where trenches 220 are desired, and then etching the sacrificial material 218 and ILD 210 in alignment with the photoresist mask 222. In an embodiment of the present invention, trench 220 is etched with an etchant which etches interlayer dielectric 210 and sacrificial material 218 at an approximately 1:1 ratio so that the formed trench 220 has a planar bottom surface as illustrated in FIG. 2F. Trench 220 can be anisotropically etched utilizing a reactive ion etching (RIE) process with a carbon/fluorine chemistry, such as but not limit to CF₄, C₂F₆ and C₄F₈. Additionally, other constituents can be added to the etch chemistry, such as but not limited to argon (Ar), nitrogen (N₂) and oxygen (0₂). Trench 220 is etched into the top portion of ILD 210 to a depth which defines the thickness desired for the subsequently formed interconnect portion of the dual damascene structure.

After forming trench 220, photoresist mask 222 can be removed utilizing well known processes. Next, the remaining portion of sacrificial material 218 in via opening 212 and on top of ILD 210 is removed as illustrated in FIG. 2G. Sacrificial material 218 is removed with an etchant which is does not etch or only slightly etches ILD 210 so that the trench 220 and via opening 212 are preserved in ILD 210 as illustrated in FIG. 2G. Additionally, sacrificial material 218 is removed with an etchant which does not etch or only slightly etches partial gap fill material 216 so that at least a portion of the gap fill material 216 remains in via opening 212 to protect the underlying metal interconnect 202 from attack by the chemical used to remove the sacrificial material 218. In an embodiment of the present invention, the sacrificial material 218 is removed with a wet etchant comprising tetramethylammonia hydroxide (TMAH). Examples of suitable solutions to remove a SLAM material include but are not limited to XM-237 and XM-220 manufactured by Baker Corporation. After removal of sacrificial material 218 from via opening 212, via opening 212 and trench 220 can be cleaned utilizing well known techniques. For example, via opening 212 and trench 220 can be cleaned with solutions comprising buffered HF or dilute HF solutions in aqueous or organic mediums. In an embodiment of the present invention, after removing sacrificial material 218 and cleaning trench 220 and via opening 212, at least a portion of partial gap fill material 216 remains on underlying interconnect 202 as shown in FIG. 2G. If partial gap fill material 216 is a dielectric film, then it must be removed before the barrier layer and metal deposition process used to fill via opening 212 and trench 220. If partial gap fill material 216 is a silicon nitride dielectric, it can be removed, for example, utilizing a reactive ion etch with a chemistry comprising C₂F₆ or CH₂F₂. If partial gap fill material 216 is a conductive film, such as a corrosion resistant metal film with a low resistance, then the remaining portion of the partial gap fill material 216 need not be removed and the interconnect and via metallization formed directly thereon.

Next, as shown in FIG. 2H, a conductive film 224 is formed in via opening 212 and trench opening 220. If partial gap fill material 216 is a highly conductive film, then the metal film 224 can be formed directly onto gap fill material 216 as illustrated in FIG. 2H. In an embodiment of the present invention, the trench and via opening conductive film 224 comprises a lower barrier/adhesion layer 226 and an upper bulk film 228. In an embodiment of the present invention, the adhesion/barrier layer 226 comprises a tantalum/tantalum nitride film. A tantalum/tantalum nitride film can be formed by, for example, physical vapor deposition (PVD), chemical vapor deposition (CVD), and atomic layer deposition (ALD). In an embodiment of the present invention, the bulk conductive film 228 comprises a copper or copper alloy film. A copper or copper alloy film may be formed by, for example, electroplating or electroless deposition. In an embodiment of the present invention, conductive film 224 is blanket deposited into via opening 212 and trench 220 as well as onto the top surface of ILD 210 as shown in FIG. 2H.

Next, as shown in FIG. 2I, the top portion of the conductive metal film 224 is removed from the top surface of ILD 210 to form a dual damascene structure having a interconnect portion 230 formed in the top portion of ILD 210 and a via portion 232 formed in the lower portion of ILD 210 as illustrate in FIG. 2I. Any well known technique can be used to remove conductive film 224 from the top surface of ILD 210, such as but not limed to chemical mechanical planarization and plasma etch back. When partial gap fill material 216 is a conductive film, the via portion 232 of the dual damascene interconnect structure can include the partial gap fill material 216 or a portion of the partial gap fill material 216 as illustrated in FIG. 2H as well as conductive film 224. This completes the interconnect structure of an embodiment of the present invention. Methods of the present invention can be utilized to fabricate additional levels of interconnect utilizing the same processes, in order to electrically couple the various transistors and capacitors into a functional circuits of an integrated circuit.

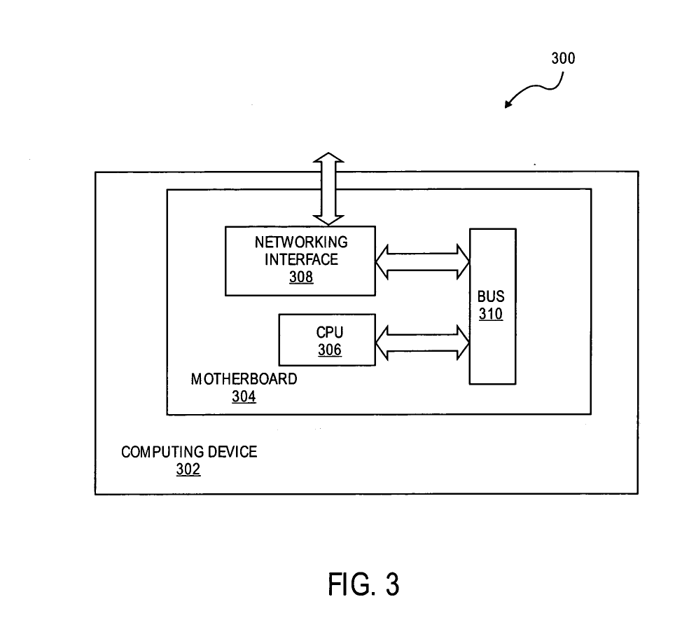

FIG. 3 illustrates a system 300 in accordance with one embodiment. As illustrated, for the embodiment, system 300 includes computing device 302 for processing data. Computing device 302 may include a motherboard 304. Motherboard 304 may include in particular a processor 306, and a networking interface 308 coupled to a bus 310. More specifically, processor 306 may comprise the earlier described dual damascene structure and/or its method of fabrication.

Depending on the applications, system 300 may include other components, including but are not limited to volatile and non-volatile memory, a graphics processor, a digital signal processor, a crypto processor, a chipset, mass storage (such as hard disk, compact disk (CD), digital versatile disk (DVD) and so forth), and so forth. One or more of these components may also include the earlier described dual damascene structure and/or its method of fabrication.

In various embodiments, system 300 may be a personal digital assistant (PDA), a mobile phone, a tablet computing device, a laptop computing device, a desktop computing device, a set-top box, an entertainment control unit, a digital camera, a digital video recorder, a CD player, a DVD player, or other digital device of the like.

We claim:

1. A method of forming an interconnect structure comprising:
forming a via opening in an interlayer dielectric over a metal layer to expose a portion of said metal layer;
partially filling said opening with a gap fill material;
filling said opening with a sacrificial material wherein said sacrificial material is formed on said gap fill material;
forming a trench in said interlayer dielectric including a portion of said sacrificial material filled opening;
removing said sacrificial material from said opening; and
filling said trench and said opening with a conductive film.

2. The method of claim 1 wherein said gap fill material is a dielectric and wherein said gap fill material is completely removed from said opening prior to filling said opening and said trench with said conductive film.

3. The method of claim 2 wherein an etchant used to remove said sacrificial material can etch said sacrificial material at least 10 times faster than said gap fill material.

4. The method of claim 1 wherein said gap fill material is a conductive gap fill material and wherein said conductive film used to fill said trench and said opening is formed in direct contact with said conductive gap fill material in said opening.

5. The method of claim 4 wherein a portion of said conductive gap fill material is removed prior to filling said trench and said opening with said conductive film.

6. The method of claim 4 wherein said conductive gap fill material is selected from the group consisting of cobalt alloys and nickel alloys.

7. The method of claim 4 wherein said conductive gap fill material is selectively deposited into said opening and onto said exposed portion of said metal layer utilizing an electroless deposition process.

8. A method of fabricating an interconnect structure comprising:
forming an interlayer dielectric having an upper portion and a lower portion over a metal interconnect;
forming an opening through said upper and lower portions of said interlayer dielectric to expose a portion of said metal interconnect;
forming a corrosion resistant metal layer in said opening in said lower portion of said interlayer dielectric and on said exposed portion of said metal interconnect;
forming a sacrificial material in said opening and on said corrosion resistant metal layer;
forming a trench in said upper portion of said interlayer dielectric wherein said trench is formed in a portion of said sacrificial material filled opening;
removing said sacrificial material from said opening; and
filling said trench and said opening with a conductive film wherein said conductive film is formed in direct contact with said corrosion resistant material.

9. The method of claim 8 wherein said corrosion resistant metal layer is formed by a selective deposition process.

10. The method of claim 9 wherein said corrosion resistant material is formed by electroless plating.

11. The method of claim 8 wherein said corrosion resistant metal layer is selected from the group consisting of cobalt alloys and nickel alloys.

12. The method of claim 8 wherein a portion of said corrosion resistant material is removed prior to filling said trench and said opening with said conductive film.

13. The method of claim 8 wherein after removing said sacrificial material from said opening, cleaning said opening with a trench cleaning solution comprising buffered HF or dilute HF in aqueous or organic mediums.

14. The method of claim 8 wherein said sacrificial material is a sacrificial light absorbing materials (SLAM).

15. The method of claim 8 wherein said metal interconnect includes a capping layer.

16. The method of claim 8 wherein said capping layer comprises a cobalt contianing film formed by an electroless deposition process.

17. An interconnect structure comprising:
a first metal interconnect formed in a first interlayer dielectric, wherein said first metal interconnect has a top surface which is co-planar with a top surface of said first interlayer dielectric;
a second interlayer dielectric having a top portion and a bottom portion formed on said first interlayer dielectric and on a portion of said first metal interconnect;
a second interconnect formed in said top portion of said second interlayer dielectric; and
a via formed in the lower portion of said second interlayer dielectric wherein said via has an upper portion in direct contact with said second metal interconnect and the lower portion in direct contact with said first metal interconnect, wherein said lower portion of said via is formed from a first conductive film and the upper portion of said via formed from a second conductive film wherein said first conductive film is different than said second conductive film.

18. The interconnect structure of claim 17 wherein said first metal film is selected from the group consisting of cobalt and nickel alloys.

19. The interconnect structure of claim 17 wherein said second metal film includes a lower barrier layer and an upper bulk conductive layer.

20. The interconnect structure of claim 19 wherein said lower barrier layer is selected from the group consisting of tantalum nitride and titanium nitride and wherein said upper bulk conductive layer is selected from the group consisting of copper and copper alloys.

21. The interconnect structure of claim 17 wherein said first conductive film is not formed on the sidewalls of said interlayer dielectric in the upper portion of said via.

22. The interconnect structure of claim 17 wherein said first metal interconnect includes a cobalt cap layer formed on a copper bulk layer.
